(19) United States
(12) Patent Application Publication
(10) Pub. No.: US 2015/0048814 A1
(43) Pub. Date: Feb. 19, 2015

(54) Absence of Voltage Indicator with Communication Network Based Secondary Power Source

(71) Applicant: Panduit Corp., Tinley Park, IL (US)

(72) Inventor: Rachel M. Bugaris, Homer Glen, IL (US)

(73) Assignee: Panduit Corp., Tinley Park, IL (US)

(21) Appl. No.: 14/453,834

(22) Filed: Aug. 7, 2014

Related U.S. Application Data
(60) Provisional application No. 61/865,381, filed on Aug. 13, 2013.

(51) Int. Cl. G01R 19/155; G01R 19/00

(52) U.S. Cl. CPC G01R 19/155; G01R 19/0084
USPC 324/76.11

(57) ABSTRACT

A system for the detection and indication of both the absence and presence of voltage is described. The system has a voltage detector module, a voltage indicator module, and a communication network based continuous secondary power source configured to enable the voltage indicator module to positively indicate the absence of voltage in the primary circuit. In some embodiments, the system can positively indicate the presence of voltage in the primary circuit such that the positive detection and indication is powered by the primary circuit itself. In some embodiments, the positive detection and indication of voltage can also be powered by the communication network based secondary power source.

### CROSS-REFERENCE TO RELATED APPLICATION

This application claims priority to U.S. Provisional Application No. 61/865,381, filed Aug. 13, 2013, the subject matter of which is hereby incorporated by reference in its entirety.

### FIELD OF THE INVENTION

The present invention relates generally to voltage detectors and indicators and specifically to indicating the absence of voltage facilitated by using a separate backup power source, independent from the source being monitored.

### BACKGROUND OF THE INVENTION

When working on or near electrical equipment, hazards such as arc flash, arc blast, and electrical shock exist when voltage is present. Standards and workplace procedures require an electrically safe work condition to be established before any work involving electrical hazards is performed. In most cases, this involves ensuring equipment is in a de-energized state. For instance, one step in the process of establishing an electrically safe work condition described in NFPA 70E includes testing for the absence of voltage.

The use of voltage detection and indication systems is increasingly common in industrial environments. These systems typically consist of circuitry hardwired to a power source within an enclosure (line or load side of a circuit breaker or disconnect) and use a series of indicators, such as LEDs, to indicate when voltage is present in a panel or compartment.

Existing voltage detectors and indicators are often powered by the same circuit that is intended to be monitored. By deriving power only from this circuit, the device is limited to only indicating the presence of voltage, not the absence. Voltage indicators typically illuminate status indicator(s) when voltage is present, however if the indicator is not illuminated, it does not guarantee that voltage is not present. In existing systems, the lack of illumination on the voltage indicator could still occur when voltage is present and instead be due to a failed LED and/or a failed device, broken wired connection, etc. Thus, these devices can only be used for pre-verification and an alternative solution is required to testing for the absence of voltage.

### SUMMARY OF THE INVENTION

A system for the detection and indication of both the absence and presence of voltage is described. The system has a voltage detector module, a voltage indicator module, and a communication network based continuous secondary power source configured to enable the voltage indicator module to positively indicate the absence of voltage in the primary circuit. In some embodiments, the system can positively indicate the presence of voltage in the primary circuit such that the positive detection and indication is powered by the primary circuit itself. In some embodiments, the positive detection and indication of voltage can also be powered by the communication network based secondary power source.

### BRIEF DESCRIPTION OF THE FIGURE

FIG. 1 shows a system overview of a voltage detection and indication system powered by the primary circuit (the source being monitored) and also by a communication network based continuous power source (such as power-over-Ethernet).

### DETAILED DESCRIPTION OF THE PREFERRED EMBODIMENTS

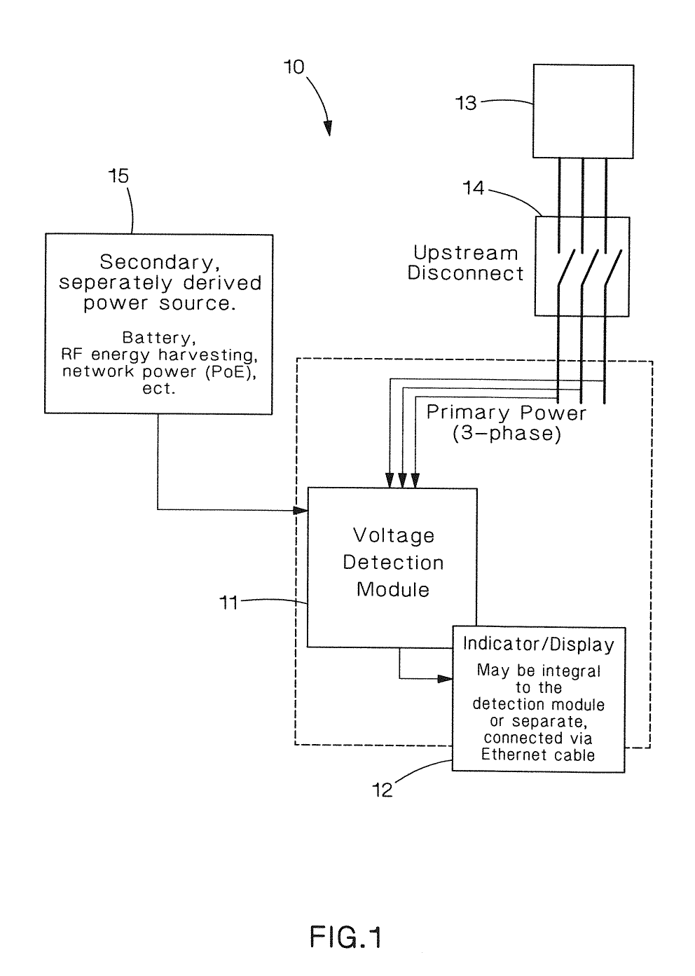

FIG. 1 shows one embodiment of a voltage detection and indication system 10. The voltage detection and indication system 10 can include a voltage detector module 11 connected to a primary circuit 13 downstream of a disconnect 14. The voltage detector module 11 is also connected to a voltage indicator module 12 and a communication network based continuous secondary power source 15 such as power-over-Ethernet.

The voltage detector module 11 houses the circuitry and logic to detect and analyze the status of the primary circuit 13. The detection circuitry is powered by two unique and separate sources, the power from the primary circuit 13 (primary power source) 13 itself, and the communication network based continuous secondary power source 15 (such as power-over-Ethernet (PoE)). The communication network based continuous secondary power source 15, is available at all times, but the device may draw power from the secondary source at all times or activate only when the primary circuit 13 is disabled. The voltage indicator module 12 displays the voltage status of the primary circuit 13 as determined by the voltage detector 11 and may also display the status of the communication network based continuous secondary power source 15. The voltage indicator module 12 may be integral to or separate from the voltage detector module 11.

The voltage indicator module 12 can be mounted external to an enclosure and may take several forms. The voltage indicator module 12 may display the presence or absence of voltage in each phase individually or all three phases collectively. The presence indicators may be powered from the primary circuit 13 and/or the network based continuous secondary power source 15, but the absence of voltage indicators will be powered by the communication network based continuous secondary power source 15. The voltage indicator 12 module can also optionally display the status of the system (health of unit, how it is functioning) as determined by the voltage detector module 11. The voltage indicator module 12 may be a series of LEDs or could incorporate a display for the purpose of indicating the nominal value of present voltage, when voltage was last detected, or more information on any other status changes. This could serve as a verification for electricians performing diagnostic work when equipment is energized, displaying a real-time indication of how much voltage is present (24V, 120V, 480V, etc.).

Powering the voltage detection and indication system 10 via the communication network based continuous power source 15 enables the voltage indicator module 11 to positively indicate when voltage is not present on the primary circuit 13. Preferably, the communication network based continuous secondary power source 15 should be reliable and function at power levels that do not create additional hazards. Network derived power, such as power-over-Ethernet (PoE) or other similar technologies, allows for such a system to function safely at non-hazardous voltage levels, even when the primary circuit 13 is not present. Thus, a positive indication for both the absence and presence of voltage can be displayed as long as power is injected over the network. Additionally, adding intelligence, via network capability, to the voltage detection and indication system 10 enables additional information to be available in real time. For instance, if multiple devices (or even other sensors) are on the same network, status from one or more devices/sensors may be factored in for the purpose of determining an overall or combined status which could then be conveyed via indication. One example is a machine with multiple energy sources. A worker may want to determine if all voltage sources have been removed prior to performing a specific task. Rather than utilizing a series of individual indications, the voltage testers could be placed at strategic points in the circuit. The status of each individual tester could be communicated via the network and the combined result indicated on a single master and/or each individual units. Having a continuous secondary power source in combination with the network communication element enables this enhanced functionality of which cominations of momentary secondary power sources and non-networked devices would not be capable.

The voltage detection and indication system 10 could be installed in several ways depending on the application. For instance, the voltage detector 11 could monitor the supply (line) side or primary power in an enclosure. However, it could also be used to monitor the load side, for the purpose of determining which phases are live, for instance in the case of a blown fuse or fuses or a failed disconnect mechanism. Similarly, this system could be applied to equipment with more than one power feed. In this scenario, each source of supply voltage would be monitored by a separate module.

Applications for this system include closed panel verification of supply voltage (particularly useful for panels with high energy levels or panels that are frequently accessed), voltage verification panels where more than one power source is available, verification of the dissipation of stored electrical energy, voltage indication of the load side of the disconnect, applications when visual inspection of the contacts/disconnect blades is not possible (applications with no enclosure window, no line of sight, etc.), indication of which phase(s) are live, i.e. blown fuse indicator when visual inspection is not possible, indication of voltage to a HMI for remote switching, and linkage to an input to a door latch (when primary voltage is present, a security latch will remain locked preventing unauthorized access).

While particular embodiments and applications of the present invention have been illustrated and described, it is to be understood that the invention is not limited to the precise construction and compositions disclosed herein and that various modifications, changes, and variations may be apparent from the foregoing without departing from the spirit and scope of the invention as described.

1. A system for the detection and indication of voltage for a primary circuit comprising:
a voltage detector module;
a voltage indicator module; and
a continuous secondary power source configured to enable the voltage indicator module to positively indicate the absence of voltage in the primary circuit.

2. The system for the detection and indication of voltage for a primary circuit of claim 1 wherein the continuous secondary power source is a communication network based power source.

3. The system for the detection and indication of voltage for a primary circuit of claim 1 wherein the continuous secondary power source is a power-over-Ethernet source.

4. The system for the detection and indication of voltage for a primary circuit of claim 1 wherein the voltage indicator is configured to positively indicate the presence of voltage.

5. The system for the detection and indication of voltage for a primary circuit of claim 4 wherein power for the positive indication of the presence of voltage is derived from the primary circuit.
